(19) United States
(12) Patent Application Publication
(10) Pub. No.: US 2026/0173331 A1
(43) Pub. Date: Jun. 18, 2026

(54) INTEGRATED HOUSING WITH COOLING CHANNELS FOR A WIRELESS CHARGING SYSTEM OF AN ELECTRIC VEHICLE AND A METHOD OF MANUFACTURING THE SAME

(71) Applicants: HYUNDAI MOTOR COMPANY, Seoul (KR); KIA CORPORATION, Seoul (KR)

(72) Inventor: Myoung Ho Lee, Hwaseong-si (KR)

(73) Assignees: HYUNDAI MOTOR COMPANY, Seoul (KR); KIA CORPORATION, Seoul (KR)

(21) Appl. No.: 19/169,510

(22) Filed: Apr. 3, 2025

(30) Foreign Application Priority Data
Dec. 17, 2024 (KR) 10-2024-0188727

(51) Int. Cl. H05K 7/20; B60L 53/12; B60L 53/302; H02J 50/70

(52) U.S. Cl. CPC H05K 7/2089; B60L 53/12; B60L 53/302; H02J 50/70

(57) ABSTRACT

An integrated housing for an electric vehicle is featuring a cooling channel and designed for mounting a receiving array facing the ground. The housing includes an upper exposed surface that contacts the vehicle's lower part, and a lower coupling surface that faces the ground and covers a predetermined area. A refrigerant flow path is defined by the space between the upper and lower surfaces, and includes both a refrigerant injection port (inlet) and a refrigerant collection port (outlet). All of these components—the upper exposed surface, lower coupling surface, refrigerant injection port, and refrigerant collection port—are integrally cast in metal.

### CROSS-REFERENCE TO RELATED APPLICATION(S)

This application is based on and claims priority to Korean Patent Application No. 10-2024-0188727, filed on Dec. 17, 2024, in the Korean Intellectual Property Office, the disclosure of which is herein incorporated by reference in its entirety.

### TECHNICAL FIELD

The present disclosure relates to an integrated housing with a cooling channel for wireless charging systems of electric vehicles and a method of manufacturing the same, and more particularly to an integrated housing with a cooling channel formed integrally with a charging housing and a method of manufacturing the same.

### BACKGROUND

The prevalence of electric vehicles is increasing.

Along with this, infrastructure and technology related to electric vehicles are steadily developing.

Electric vehicles are moved by storing electrical energy in a battery system and using the electrical energy to drive a motor.

Therefore, the amount of electrical energy that can be stored in the battery, the time required for charging, the size and weight of the battery system, and the charging method are very important technical factors.

In general, wired charging with a connector for power supply is widely used at a charging station. At the same time, research is underway to adapt wireless charging technology, which is already used in small electronic products, to electric vehicles.

Wireless charging systems transfer energy without electrical contact. By eliminating the need for physical contact between an electric vehicle and a charging device, ease of use may be improved and maintenance may be relatively simple.

However, there are still many problems that need to be solved to power electric vehicles with large battery systems using wireless charging systems.

In order to have a wireless charging system that is both efficient and reliable in energy transfer, the temperature of the system must be easily controlled.

While various technologies have been proposed for cooling wireless charging systems, there are still many problems that need to be solved, such as the complexity of the design of key equipment and the large space required for installation.

These problems limit the overall thermal management performance of wireless charging systems. In addition, the structural complexity of the system requires great initial costs to equip manufacturing facilities and increases production costs.

The statements in this Background section merely provide background information related to the present disclosure and may not constitute prior art.

### SUMMARY

The present disclosure may solve a conventional problem that a housing and a cooling facility are separately required for wireless charging of an electric vehicle.

The present disclosure may solve a conventional problem that a receiving portion configured to receive a magnetic field in a wireless charging system of an electric vehicle has a complex structure and the process and facility for manufacturing each part are not unified.

The present disclosure may solve a conventional problem that a vehicle body is exposed to strong magnetic and electric fields.

The present disclosure may solve a conventional problem that magnetic flux leakage often causes partial heat generation and charging efficiency is often reduced due to magnetic flux leakage.

Objects of the present disclosure are not limited to the aforementioned objects, and other unmentioned objects of the present disclosure should be clearly understood from the following description.

According to an embodiment of the present disclosure, an integrated housing includes a cooling channel and configured to mount a receiving array facing a ground. The integrated housing includes: an upper surface configured to be coupled to the lower part of the electric vehicle; a lower surface configured to face the ground, which is positioned opposite the upper surface, the lower coupling surface having a predetermined area; a refrigerant flow path, which is a space formed between the upper surface and the lower surface; a refrigerant injection port, which is or serves as an inlet connected to the refrigerant flow path; and a refrigerant collection port, which is or serves as an outlet connected to the refrigerant flow path. The upper exposed surface, the lower coupling surface, the refrigerant injection port, and the refrigerant collection port are made of metal and formed integrally as a single structure.

According to an embodiment of the present disclosure, each of the upper surface and the lower surface may be disposed in a horizontal direction while having a large area and a relatively small thickness.

According to an embodiment of the present disclosure, a refrigerant may be introduced into the refrigerant flow path through the refrigerant injection port and may be discharged from the refrigerant flow path through the refrigerant collection port.

According to an embodiment of the present disclosure, the refrigerant flow path may include a plurality of flow guides configured to guide the refrigerant introduced through the refrigerant injection port and discharged through refrigerant collection port along a predetermined channel.

According to an embodiment of the present disclosure, the refrigerant flow path may include a plurality of magnetic members, each magnetic member of the plurality of magnetic members having a vertically straight columnar shape having a constant sectional area. According to an embodiment of the present disclosure, a lower end of each magnetic member of the plurality of magnetic members is connected to the lower surface and an upper end of each magnetic member of the plurality of magnetic members is connected to the upper surface, each magnetic member of the magnetic members being magnetic.

According to an embodiment of the present disclosure, each magnetic member of the plurality of magnetic members may include a first polarized portion, which is a part extending upward from a middle thereof, and a second polarized portion, which is a part extending downward from the middle thereof, the second polarized portion being straightly connected to a lower end of the first polarized portion, and the first polarized portion and the second polarized portion may be made of magnetic materials having different polarities.

According to an embodiment of the present disclosure, a method of manufacturing an integrated housing with a cooling channel includes: a mold manufacturing step including machining an upper molding surface of a lower surface of an upper mold and a lower molding surface of an upper surface of a lower mold such that a cavity forms a predetermined shape of a housing; a sand core manufacturing step including manufacturing a sand core to be received in the cavity through a core manufacturing mold such that a refrigerant flow path is formed in the integrated housing; a sand core seating step including seating the manufactured sand core to the lower molding surface formed on the lower mold; a mold assembly step including coupling the upper mold and the lower mold to each other such that the lower molding surface formed on the lower mold and the upper molding surface formed on the upper mold engage with each other to form the cavity having the pre-set housing shape; a melt injection and low-pressure casting step including injecting a molten metal material into the cavity through a gate at a low pressure; a withdrawal and desanding step including, after the metal material in the casting mold (or in the cavity) solidifies into the housing shape, separating the upper mold and the lower mold from each other, withdrawing the solidified metal formed by the solidifying the molten metal injected into the cavity, and removing the sand core remaining in the refrigerant flow path; and a post-treatment step including performing treatment to improve completeness of the integrated housing.

According to an embodiment of the present disclosure, the mold manufacturing step may further include a magnetic material embedding step including embedding magnetic materials at different positions (e.g., at pre-set positions) on the upper molding surface to form a plurality of first embedding portions and, in a mold assembly state, embedding additional magnetic materials in parts of or in regions of the lower molding surface located vertically downwardly of or beneath the plurality of first embedding portions to form a plurality of second embedding portions.

According to an embodiment of the present disclosure, the sand core manufacturing step may further include a magnetic core forming step including installing a magnetic inserting bar in the sand core in a vertical orientation (e.g., vertically straight) on each second embedding portion of the plurality of second embedding portions in the state in which the sand core is seated on the lower molding surface.

According to an embodiment of the present disclosure, the refrigerant flow path may include a plurality of flow guides configured to guide a refrigerant introduced through a refrigerant injection port and discharged through a refrigerant collection port along a pre-set channel.

According to an embodiment of the present disclosure, an integrated housing with a cooling channel for a wireless charging system of an electric vehicle includes: a first surface configured to be coupled to the electric vehicle; a second surface configured to face a ground and positioned opposite the first surface; a refrigerant flow path defined by a space formed between the first surface and the second surface; a refrigerant injection port configured to serve as an inlet connected to the refrigerant flow path; and a refrigerant collection port configured to serve as an outlet connected to the refrigerant flow path. The first surface, the second surface, the refrigerant injection port, and the refrigerant collection port are made of metal and integrally formed by a casting process.

According to an embodiment of the present disclosure, each of the first surface and the second surface may be oriented horizontally.

According to an embodiment of the present disclosure, a refrigerant may be introduced into the refrigerant flow path through the refrigerant injection port and discharged from the refrigerant flow path through the refrigerant collection port.

According to an embodiment of the present disclosure, the refrigerant flow path may include a plurality of flow guides configured to guide the refrigerant introduced through the refrigerant injection port and discharged through the refrigerant collection port along a pre-set channel.

According to an embodiment of the present disclosure, the refrigerant flow path may further include a plurality of magnetic members, each magnetic member of the plurality of magnetic members having a vertical columnar shape with a constant cross-sectional area.

According to an embodiment of the present disclosure, a lower end of each of the plurality of magnetic members may be connected to the second surface and an upper end of each of the plurality of magnetic members may be connected to the first surface.

According to an embodiment of the present disclosure, each magnetic member of the plurality of magnetic members may include a first polarized portion extending upward from a middle portion, and a second polarized portion extending downward from the middle portion and directly connected to a lower end of the first polarized portion. The first and second polarized portions may be made of magnetic materials having opposite polarities.

### BRIEF DESCRIPTION OF THE DRAWINGS

FIG. 1 is a view schematically showing an example wireless charging system of an electric vehicle;

FIG. 2 is a view illustrating a main body manufactured such that a receiving array, a cooling module, and the like can be respectively assembled in an example wireless charging system of the electric vehicle;

FIG. 3 is a perspective view showing a lower case and an integrated charging housing with a cooling channel according to an embodiment of the present disclosure;

FIG. 4A is a plan view of the integrated charging housing with the cooling channel according to an embodiment of the present disclosure;

FIG. 4B is a bottom view of the integrated charging housing with the cooling channel according to an embodiment of the present disclosure;

FIG. 5 is a view illustrating the schematic sectional shape of the integrated charging housing with the cooling channel according to an embodiment of the present disclosure;

FIGS. 6A and 6B is a view illustrating that magnetic flux leakage is reduced through the integrated charging housing with the cooling channel according to an embodiment of the present disclosure;

FIGS. 7A and 7B are views showing a casting mold manufactured to cast the integrated charging housing with the cooling channel according to an embodiment of the present disclosure;

FIG. 8 is a view showing a magnetic core configured to form a refrigerant flow path and install a magnetic member in the integrated charging housing with the cooling channel according to an embodiment of the present disclosure; and

FIG. 9 is a flowchart illustrating a method of manufacturing the integrated charging housing with the cooling channel according to an embodiment of the present disclosure.

The drawings described herein are for illustration purposes only and are not intended to limit the scope of the present disclosure in any way.

### DETAILED DESCRIPTION

Hereinafter, embodiments disclosed herein are described in detail with reference to the accompanying drawings.

Identical or similar components are denoted by identical or similar reference numerals, and redundant descriptions may be omitted.

When a component is referred to as being “connected” or “coupled” to another component, the component may be directly connected or coupled to the other component or there may be other components therebetween.

On the other hand, when a component is referred to as being “directly connected” or “directly coupled” to another component, it is meant that there is no other component therebetween.

In this specification, the term “including” or “having” indicates the presence of the features, steps, operations, components, parts, or combinations thereof described herein, without excluding any one thereof.

A first direction (X-axis direction), a second direction (Y-axis direction), and a third direction (Z-axis direction) described herein are used to describe a solid shape in a three-dimensional space, and are orthogonal to each other.

When a component, device, element, apparatus, or the like of the present disclosure is described as having a purpose or performing an operation, function, or the like, the component, device, element, apparatus, or the like should be considered herein as being “configured to” meet that purpose or to perform that operation or function.

The present disclosure relates to an integrated housing with a cooling channel for wireless charging systems of electric vehicles and a method of manufacturing the same.

First, an integrated housing with a cooling channel for wireless charging systems of electric vehicles according to an embodiment of the present disclosure is described.

The integrated housing with the cooling channel according to an embodiment of the present disclosure is mounted in a lower part of an electric vehicle 1 to prevent a temperature rise and a decrease in charging efficiency that may occur during a wireless charging process.

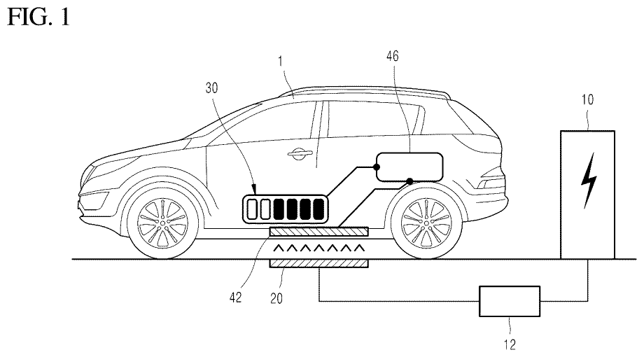

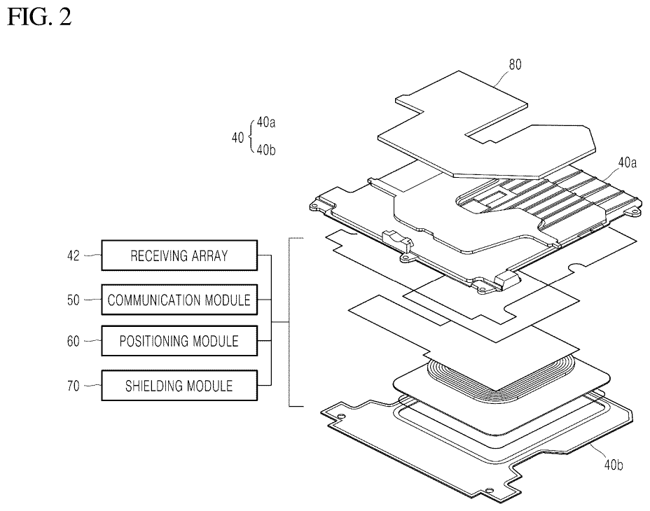

FIG. 1 is a view schematically showing an example wireless charging system of an electric vehicle 1, and FIG. 2 is a view illustrating a main body manufactured such that a receiving array 42, a cooling module, and the like can be respectively assembled in the example wireless charging system of the electric vehicle 1.

As shown in FIGS. 1 and 2, in the wireless charging system of the electric vehicle 1, current is generally converted through a supply inverter 12 connected to a charging station 10, and the converted current forms a magnetic field in a predetermined area through the transmitting array.

The electric vehicle 1 is provided with a receiving array 42 configured to receive the magnetic field formed through the transmitting array 20. The receiving array 42 is guided to a predetermined position to receive the magnetic field transmitted through the transmitting array 20, and electrical energy converted again via a receiving rectifier 46 is stored in a battery pack 30.

As shown in FIG. 2, the electric vehicle 1 includes a main body 40 configured to form a framework and coupled to a vehicle body and a receiving array 42, a communication module 50, a positioning module 60, and a shielding module 70 coupled to the main body 40. As used herein, a main body 40 may generally be referencing any one of or be collectively referencing 40a and 40b in FIG. 2.

In addition, an insert cooling module 80 configured to cool the heat transferred to the main body 40, including the receiving array 42, must be further mounted.

Such a structure has a complex assembly process and a high production unit cost, and occupies a large amount of space in the lower part of the electric vehicle 1.

An integrated housing with a cooling channel according to an embodiment of the present disclosure is proposed to solve these conventional problems.

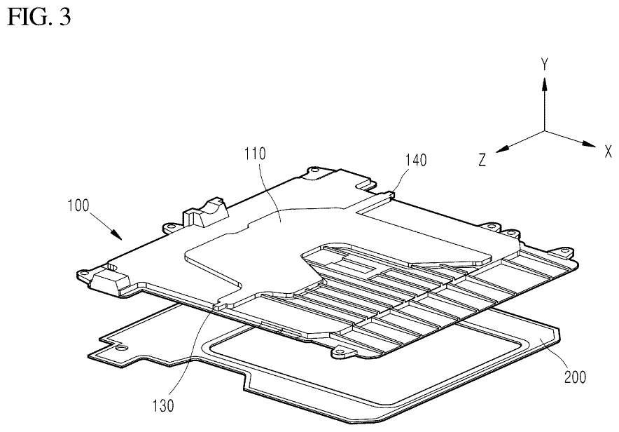

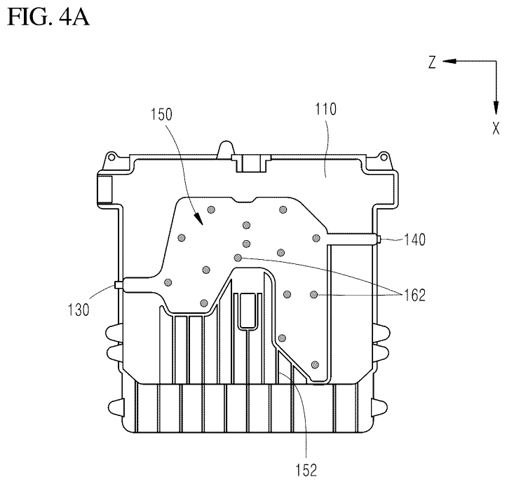

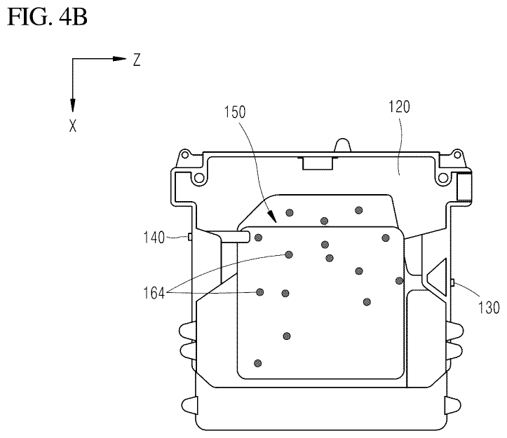

FIG. 3 is a perspective view showing a lower case 200 and an integrated charging housing 100 with a cooling channel according to an embodiment of the present disclosure. FIGS. 4A and 4B are a plan view and a bottom view, respectively, of the integrated charging housing 100 with the cooling channel according to an embodiment of the present disclosure.

As shown in FIGS. 3 and 4A-4B, the integrated housing with the cooling channel according to an embodiment of the present disclosure is coupled to the lower part of the electric vehicle 1 and is manufactured such that the receiving array 42 can be installed in a flat orientation facing the ground. In other words, the receiving array 42 is installed on the integrated housing in the flat orientation facing the ground.

The integrated housing with the cooling channel according to an embodiment of the present disclosure includes an upper exposed surface 110, a lower coupling surface 120, a refrigerant flow path 150, a refrigerant injection port 130, and a refrigerant collection port 140.

In addition, by integrating the main parts, each including a magnetic member 160 therein, into a single metal structure, the manufacturing process may be simplified and the structural strength and heat transfer efficiency may be increased.

The charging housing 100 may be made of lightweight metal, such as an aluminum alloy. Through a casting process, the main parts, including the upper exposed surface 110 and the lower coupling surface 120, are formed into a single structure.

Such a one-piece structure may minimize the number of parts and simplify an assembly process.

The shape or dimensions of the upper exposed surface 110 and the lower coupling surface 120 of the charging housing 100 according to an embodiment of the present disclosure may be customized according to the shape of the lower part of the electric vehicle 1, the conditions under which a wireless charging module is disposed, and the like.

The charging housing 100 may be formed in a flat shape with a relatively small thickness.

The upper exposed surface 110 is a flat metal surface that is in tight contact with the lower part of the electric vehicle 1 and is directly affected by the heat that may be generated by a charging pad or the receiving array 42.

The lower coupling surface 120 faces toward the ground and stably supports the charging housing 100. The lower coupling surface 120 may have an additional stiffener, such as ribs, and may be designed to reduce the impact of shock or vibration that may be generated while the electric vehicle 1 is being driven and to increase structural stability.

The lower coupling surface 120 is formed to have a predetermined area while facing the ground, which is opposite the upper exposed surface 110.

A refrigerant flow path 150 is formed between the upper exposed surface 110 and the lower coupling surface 120. The refrigerant flow path 150 forms a channel for a refrigerant to circulate and may be formed to have a complex shape.

The refrigerant flow path 150 may be formed through a casting process using a sand core, and when the sand core is removed after solidification of a product, the refrigerant flow path 150 is formed in the charging housing 100 as a hollow passage.

The refrigerant flow path 150 may be generally shaped to allow uniform circulation in the charging housing 100, depending on embodiments to which the present disclosure is applied, and may also be designed to allow for more efficient cooling of heat generated in certain sections.

A plurality of flow guides 152 may be formed in the refrigerant flow path 150, and the flow guides 152 may control the flow of the refrigerant or induce vortices.

The refrigerant is introduced through the refrigerant injection port 130, which is an inlet connected to the refrigerant flow path 150. The refrigerant absorbs heat while circulating along a predetermined channel, and is discharged (collected) to the outside through the refrigerant collection port 140, which is an outlet connected to the refrigerant flow path 150.

Each of the refrigerant injection port 130 and the refrigerant collection port 140 may be implemented as a metal tubular part configured to connect the refrigerant flow path 150 formed in the charging housing 100 to the outside, and may be integrally formed with the charging housing 100 in a casting step.

The refrigerant injected through the refrigerant injection port 130 circulates through the refrigerant flow path 150 and is then discharged (collected) to the outside through the refrigerant collection port 140, which is repeated to control heat generation.

In the integrated housing with the cooling channel according to an embodiment of the present disclosure, the lower case 200 may be coupled to the lower coupling surface 120, and the receiving array 42, the communication module 50, the positioning module 60, the shielding module 70, and the like may be installed between the lower coupling surface 120 and the lower case 200.

The refrigerant flow path 150 formed between the upper exposed surface 110 and the lower coupling surface 120 may be provided with a plurality of magnetic members 160, each of the magnetic members being formed in the shape of a vertically extending column.

The plurality of magnetic members 160 may be provided in the refrigerant flow path 150, and may be disposed at predetermined positions.

The part of the magnetic member 160 extending upward from the middle thereof forms a first polarized portion 162, and the part of the magnetic member 160 extending downward from the middle thereof forms a second polarized portion 164.

The first polarized portion 162 and the second polarized portion 164 are made of magnetic materials having different polarities.

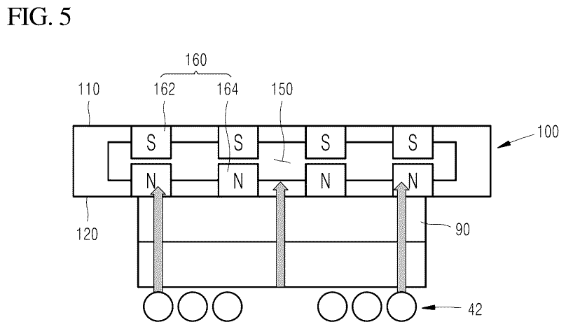

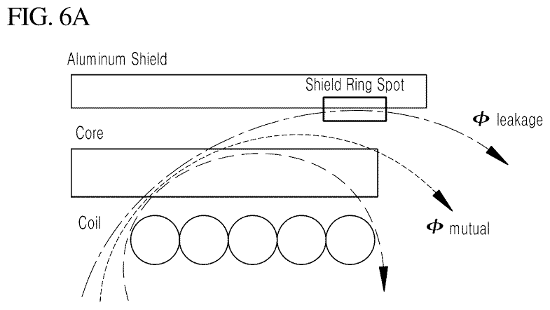

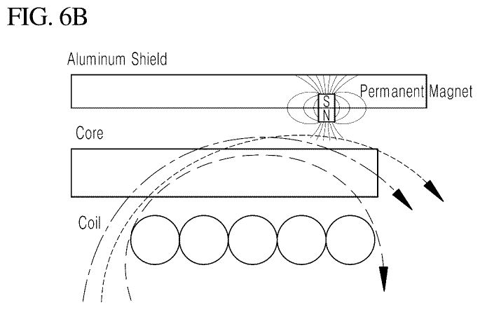

FIG. 5 is a view illustrating the schematic sectional shape of the integrated charging housing 100 with the cooling channel according to an embodiment of the present disclosure. FIGS. 6A and 6B are views illustrating that magnetic flux leakage is reduced through the integrated charging housing 100 with the cooling channel according to an embodiment of the present disclosure.

As shown in FIGS. 5 and 6A-6B, the charging housing 100 includes the refrigerant flow path 150 formed between the upper exposed surface 110 and the lower coupling surface 120. The plurality of magnetic members 160 is provided at predetermined positions in the refrigerant flow path 150.

The first polarized portion 162 and the second polarized portion 164 are disposed at the upper part and the lower part of each magnetic member 160, respectively, so as to be vertically aligned with each other while having the same sectional area.

Specifically, the first polarized portion 162 may have the S pole of a magnet, and the second polarized portion 164 may have the N pole of the magnet.

The magnetic member 160 disposed at the predetermined position has the effect of suppressing leakage magnetic flux that may be generated in a vehicle body direction from a utility module 90 installed to perform a predetermined function, including the receiving array 42.

Thus, it is possible to prevent transfer of heat to the vehicle body, including the charging housing 100, due to magnetic flux leakage.

The magnetic members 160 provided in the refrigerant flow path 150 of the charging housing 100 may suppress magnetic flux leakage and minimize the heat generation, whereby it is possible to prevent the deterioration of charging efficiency and to reduce the energy consumed for cooling.

A method of manufacturing the integrated housing with the cooling channel as described above is described.

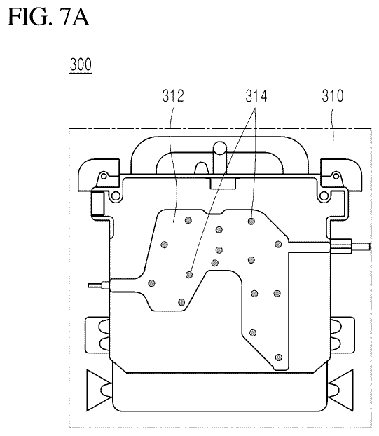

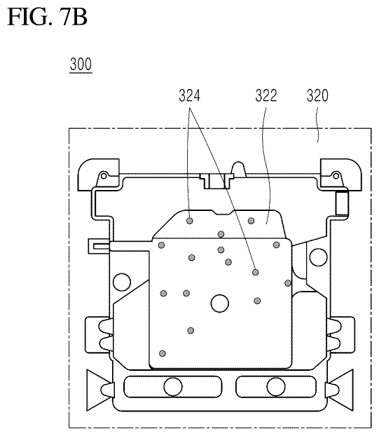

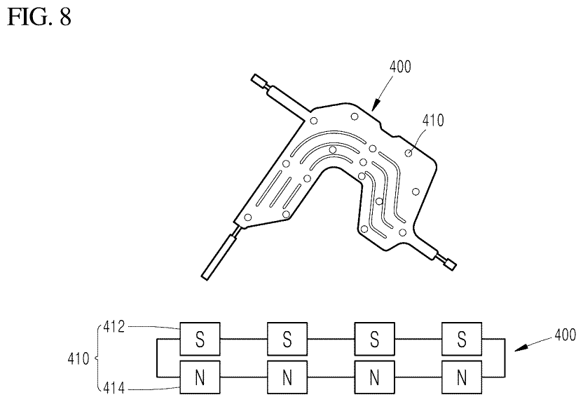

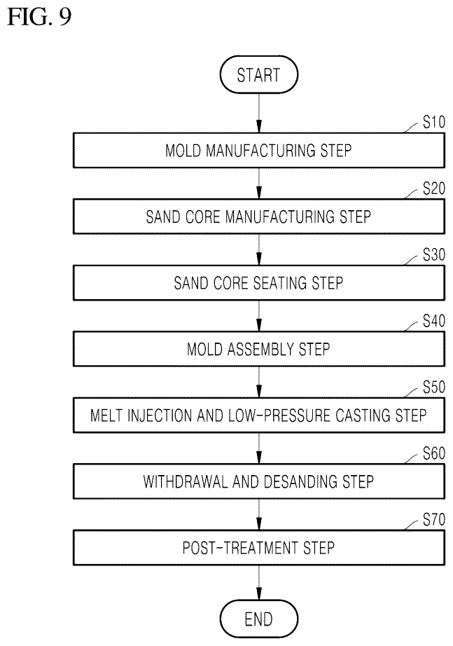

FIGS. 7A and 7B are views showing a casting mold 300 manufactured to cast the integrated charging housing 100 with the cooling channel according to an embodiment of the present disclosure, FIG. 8 is a view showing a magnetic core 400 configured to form the refrigerant flow path 150 and install the magnetic member 160 in the integrated charging housing 100 with the cooling channel according to an embodiment of the present disclosure, and FIG. 9 is a flowchart illustrating a method of manufacturing the integrated charging housing 100 with the cooling channel according to an embodiment of the present disclosure.

As shown in FIGS. 7-9, the method of manufacturing the integrated housing with the cooling channel according to an embodiment of the present disclosure includes a mold manufacturing step (S10), a sand core manufacturing step (S20), a sand core seating step (S30), a mold assembly step (S40), a melt injection and low-pressure casting step (S50), a withdrawal and desanding step (S60), and a post-treatment step (S70).

In the mold manufacturing step (S10), an upper mold 310 and a lower mold 320 are precisely machined to form a cavity corresponding to the outline of the charging housing 100. An upper molding surface 312 is precisely machined on a lower surface of the upper mold 310, a lower molding surface 322 is precisely machined on an upper surface of the lower mold 320, and the shape of the cavity is formed through the upper molding surface 312 and the lower molding surface 322.

In the sand core manufacturing step (S20), a sand core to be received in the cavity is manufactured through a core manufacturing mold such that the refrigerant flow path 150 can be formed in the charging housing 100. In the sand core manufacturing step (S20), the shape of the sand core is formed so as to correspond to the shape of the refrigerant flow path 150 to be formed, and the magnetic member 160 may be pre-coupled to the sand core so as to be fixed at a predetermined position in an upright state.

The sand core seating step (S30) is a step of seating the manufactured sand core to the lower molding surface 322 formed on the lower mold 320.

In the mold assembly step (S40), the upper mold 310 and the lower mold 320 are coupled to each other such that the lower molding surface 322 formed on the lower mold 320 and the upper molding surface 312 formed on the upper mold 310 engage with each other to form a cavity having the shape of the charging housing 100.

In the melt injection and low-pressure casting step (S50), a metal material molten in a melting furnace 500 is injected into the cavity through a gate 330 at a low pressure.

Low-pressure casting may homogenize the metallographic texture, prevent damage to the sand core, and is suitable for reproducing complex shapes of the refrigerant flow path 150 and the flow guide 152.

In the withdrawal and desanding step (S60), after the metal material in the casting mold 300 solidifies into the shape of the charging housing 100, the upper mold 310 and the lower mold 320 are separated from each other, the manufactured integrated charging housing 100 is withdrawn, and the sand core remaining in the refrigerant flow path 150 is removed.

The post-treatment step (S70) is a step of cleaning and polishing the surface of the charging housing 100 to improve the completeness after the sand core is removed.

The mold manufacturing step (S10) may further include a magnetic material embedding step. Magnetic materials are embedded at different positions in the upper molding surface 312 to form a plurality of first embedding portions 314, and in a mold assembly state, magnetic materials having opposite polarity to the magnetic materials embedded in the first embedding portions 314 are embedded in the parts of the lower molding surface 322 located vertically downwardly of the first embedding portions 314 to form second embedding portions 324.

The sand core manufacturing step (S20) may further include forming a magnetic core 400.

In the step of forming the magnetic core 400, a magnetic inserting bar 410 may be installed vertically straight on each of the second embedding portions 324 in the sand core in the state in which the sand core is seated on the lower molding surface 322.

The upper part of the inserting bar 410 installed vertically straight on each second embedding portion 324 through the step of forming the magnetic core 400 may be a first polarizer 412, and the lower part of the inserting bar may be a second polarizer 414.

The first polarizer 412 and the second polarizer 414 have the same section and form the inserting bar 410 in the shape of a vertical column.

Each of the inserting bars 410 of the magnetic core 400 thus manufactured is utilized as a magnetic member 160 including a first polarity portion 162 and a second polarity portion 164 in the finished charging housing 100 product.

According to the present disclosure, the structure of a wireless receiving portion for wireless charging of an electric vehicle is simplified, whereby manufacture may be made easier and the manufacturing cycle time may be shortened.

According to the present disclosure, it is possible to prevent a strong magnetic field from affecting a specific circuit or to prevent a heat generation phenomenon due to interaction between the magnetic field and metal parts.

According to the present disclosure, magnetic flux leakage may be significantly reduced, thereby increasing charging efficiency.

Effects of the present disclosure are not limited to the aforementioned effects, and other unmentioned effects of the present disclosure should be clearly understood by those having ordinary skill in the art from the above description.

Embodiments of the present disclosure have been described above with reference to the drawings. The described embodiments and the drawings are given by way of example, and it is apparent that the present disclosure can be variously modified within the scope of the disclosed technical ideas.

The described embodiments are to be considered as part of the present disclosure, and the scope of the present disclosure is not limited to the described embodiments.

The scope of the present disclosure is to be determined by the technical ideas recited in the claims.

Even if the described embodiments do not explicitly describe the operation or effect of a specific construction, the operation or effect that can be predicted by the construction is within the scope of the present disclosure.

What is claimed is:

1. An integrated housing for a wireless charging system of an electric vehicle, the integrated housing including a cooling channel and configured to mount a receiving array facing a ground, the integrated housing comprising:
an upper surface configured to be coupled to a lower part of the electric vehicle;
a lower surface configured to face the ground and positioned opposite the upper surface;
a refrigerant flow path defined by a space formed between the upper surface and the lower surface;
a refrigerant injection port configured to serve as an inlet connected to the refrigerant flow path; and
a refrigerant collection port configured to serve as an outlet connected to the refrigerant flow path,
wherein the upper surface, the lower surface, the refrigerant injection port, and the refrigerant collection port are made of metal and integrally formed as a single structure.

2. The integrated housing according to claim 1, wherein each of the upper surface and the lower surface is oriented horizontally.

3. The integrated housing according to claim 1, wherein a refrigerant is introduced into the refrigerant flow path through the refrigerant injection port and discharged from the refrigerant flow path through the refrigerant collection port.

4. The integrated housing according to claim 3, wherein the refrigerant flow path comprises a plurality of flow guides configured to guide the refrigerant introduced through the refrigerant injection port and discharged through the refrigerant collection port along a pre-set channel.

5. The integrated housing according to claim 4, wherein the refrigerant flow path further comprises a plurality of magnetic members, each magnetic member of the plurality of magnetic members having a vertical columnar shape with a constant cross-sectional area.

6. The integrated housing according to claim 5, wherein a lower end of each magnetic member of the plurality of magnetic members is connected to the lower surface and an upper end of each magnetic member of the plurality of magnetic members is connected to the upper surface.

7. The integrated housing according to claim 5, wherein each magnetic member of the plurality of magnetic members comprises:
a first polarized portion extending upward from a middle portion; and
a second polarized portion extending downward from the middle portion and directly connected to a lower end of the first polarized portion,
wherein the first and second polarized portions are made of magnetic materials having opposite polarities.

8. A method of manufacturing an integrated housing with a cooling channel, the method comprising:
machining an upper molding surface on a lower face of an upper mold and a lower molding surface on an upper face of a lower mold such that a cavity having a pre-set housing shape is formed;
producing a sand core via a core manufacturing mold such that a refrigerant flow path is formed in the integrated housing;
seating the sand core on the lower molding surface of the lower mold;
coupling the upper mold and the lower mold such that the lower molding surface and the upper molding surface engage to form the cavity having the pre-set housing shape;
injecting a molten metal material into the cavity through a gate at low pressure;
after solidification of the molten metal injected into the cavity, separating the upper and lower molds;
withdrawing solidified metal formed by the solidification of the molten metal injected into the cavity;
removing the sand core remaining in the refrigerant flow path; and
performing treatment to improve completeness of the integrated housing.

9. The method according to claim 8, further comprising:
embedding magnetic materials at pre-set positions on the upper molding surface to form a plurality of first embedding portions, and,
in an assembled mold state, embedding additional magnetic materials in regions of the lower molding surface located vertically beneath the plurality of first embedding portions to form a plurality of second embedding portions.

10. The method according to claim 9, further comprising installing a magnetic inserting bar in the sand core in a vertical orientation on each second embedding portion of the plurality of second embedding portions in a state in which the sand core is seated on the lower molding surface.

11. The method according to claim 8, wherein the refrigerant flow path comprises a plurality of flow guides configured to guide a refrigerant introduced through a refrigerant injection port and discharged through a refrigerant collection port along a pre-set channel.

12. An integrated housing with a cooling channel for a wireless charging system of an electric vehicle, the integrated housing comprising:
a first surface configured to be coupled to the electric vehicle;
a second surface configured to face a ground and positioned opposite the first surface;
a refrigerant flow path defined by a space formed between the first surface and the second surface;
a refrigerant injection port configured to serve as an inlet connected to the refrigerant flow path; and
a refrigerant collection port configured to serve as an outlet connected to the refrigerant flow path,
wherein the first surface, the second surface, the refrigerant injection port, and the refrigerant collection port are made of metal and integrally formed by a casting process.

13. The integrated housing according to claim 12, wherein each of the first surface and the second surface is oriented horizontally.

14. The integrated housing according to claim 12, wherein a refrigerant is introduced into the refrigerant flow path through the refrigerant injection port and discharged from the refrigerant flow path through the refrigerant collection port.

15. The integrated housing according to claim 14, wherein the refrigerant flow path comprises a plurality of flow guides configured to guide the refrigerant introduced through the refrigerant injection port and discharged through the refrigerant collection port along a pre-set channel.

16. The integrated housing according to claim 15, wherein the refrigerant flow path further comprises a plurality of magnetic members, each magnetic member of the plurality of magnetic members having a vertical columnar shape with a constant cross-sectional area.

17. The integrated housing according to claim 16, wherein a lower end of each magnetic member of the plurality of magnetic members is connected to the second surface and an upper end of each magnetic member of the plurality of magnetic members is connected to the first surface.

18. The integrated housing according to claim 16, wherein each magnetic member of the plurality of magnetic members comprises:
a first polarized portion extending upward from a middle portion; and
a second polarized portion extending downward from the middle portion and directly connected to a lower end of the first polarized portion,
wherein the first and second polarized portions are made of magnetic materials having opposite polarities.
